(19) United States
(12) Patent Application Publication
(10) Pub. No.: US 2025/0279338 A1
(43) Pub. Date: Sep. 4, 2025

(54) VARIABLE SOURCE FEEDBACK TAP

(71) Applicant: Robert Bosch GmbH, Stuttgart (DE)

(72) Inventor: Jonathan Winkler, Sonnenbuehl (DE)

(21) Appl. No.: 19/065,628

(22) Filed: Feb. 27, 2025

(30) Foreign Application Priority Data
Mar. 1, 2024 (DE) 10 2024 201 924.0

(51) Int. Cl. H01L 23/495; H01L 25/18; H10D 1/47

(52) U.S. Cl. CPC H01L 23/49548; H01L 23/49575; H10D 1/47; H01L 25/18

(57) ABSTRACT

A lead frame for a power module for implementing a variable source feedback tap. The lead frame includes a first part and a second part. The first part is formed separately from the second part. The first part has at least one gate, one source and one power source. The gate, the source, and the power source are spaced apart from one another in a side-by-side manner. A variable source feedback tap is made between the power source and the source by a contact connection.

### FIELD

The present invention relates to a lead frame for a power module for implementing a variable source feedback tap. The lead frame has a gate, a source and a power source, which are arranged next to one another and spaced apart. Furthermore, the present invention relates to the use of the lead frame in a power module.

### BACKGROUND INFORMATION

Single-switch power modules such as the STPAK from STMicroelectronic and others, for example from Wolfspeed, are described in the related art. They are used in Tesla inverters, among other things. This type of power module package is characterized in that one or more, typically two semiconductor components (SiC MOSFETs or Si IGBTs, and optionally with a diode) are placed in this power module on an insulated AMB substrate. The package typically has a copper lead frame, which is used as a high-current contact and as a signal contact. Generally, one side is connected to the AMB substrate and the other side to the front of the semiconductor by soldering. The control terminals of the semiconductor are typically bonded to a potential island on the AMB (active metal brazing) carrier using bond wires, and from there to the lead frame, also using bond wires. The entire assembly is packaged using the transfer molding method. The lower metallization of the AMB remains free to allow the modules to be sintered or soldered onto a heat sink later.

The source feedback (SFB) effect or tap is described in the related art. Here, part of the load current path runs in the control current path, which creates negative feedback. The voltage induced by a load current change at the common parasitic inductance is coupled into the control circuit and can lead to a reduction of the gate driver voltage and thus to an improved resistance to short circuits, in particular in the event of a short circuit. In a typical implementation, the source feedback effect/tap is predefined by a stamped lead frame.

### SUMMARY

According to the present invention, a lead frame for a power module for implementing a variable source feedback tap is provided. According to an example embodiment of the present invention, the lead frame includes a first part and a second part, wherein the first part is formed separately from the second part. The first part has at least a gate, a source and a power source, wherein the gate, the source and the power source are spaced apart from one another in a side-by-side manner, and wherein the variable source feedback tap between the power source and the source is made by a contact connection.

A power module is an electronic component for controlling or regulating a power, such as a current or a voltage, in an electronic circuit. For the purposes of the present invention, a lead frame is provided by one or more structured printed circuit boards made of a conductive material such as copper. They form part of the housing of a power module and the interface for the electrical connections between the module and the printed circuit board or other components in an electronic system.

The lead frame according to the present invention has a first part and a second part, wherein both parts are fastened to, for example, semiconductor components comprising the power module. In this case, a source feedback tap through the first part according to the present invention of the lead frame is proposed in one formation of the lead frame. According to the solution according to the present invention, a source feedback tap is understood to be a feedback signal that acts on the control circuit by changing the current in the load circuit. A rapid increase in the load current leads to negative feedback in the drive circuit, which counteracts the driving of the power transistor so that a gate voltage of the power transistor is transiently reduced.

For the purposes of the present invention, a power source is a terminal that is intended solely for the load current (AC and/or DC) that flows into a connected sink or is supplied by a connected source. A gate is an element in an electronic circuit that controls a current flow. For example, a particular electronic state can be activated or deactivated by applying an external voltage to the gate. The gate also functions, for example, as a control point for the flow of information or energy within a circuit, such as the power module. The source is a starting point for the current flow and contributes to a flow of energy within a circuit. The elements of the circuit are supplied with charge carriers through an electrical connection to the source.

In the solution according to an example embodiment of the present invention, the control terminal for the contact of the source is formed directly on the power source. In this case, a connection point within the mold body of the power module can be moved along the power source. This results in an adjustable source feedback effect due to the common inductance in a load and a control circuit. This effect can be used advantageously, for example in order to allow countermeasures to be taken in the event of a short circuit, thereby increasing the resistance to short circuits. As the tap distance increases, the effect of the source feedback tap becomes greater since the inductance of the common load and control path increases. In addition to adjusting the source feedback tap, the solution according to the present invention allows a common inductance in the load and control circuit to be varied. For this purpose, a cross section of the lead frame is varied by means of recesses (e.g., elongated holes), wherein the recesses can be designed in any orientation, including longitudinal, transverse or oblique.

A soldered connection is suitable as a contact connection for a variable source feedback tap. Advantageously, the source feedback tap in the solution according to the present invention is realized by a soldered connection between the power source and the source instead of by a stamped web in the lead frame.

According to an example embodiment of the present invention, in the production of the assembly, in particular in the construction of a power module having the lead frame according to the present invention, the contact connection is made by making a soldered connection between the source and the power source. As an alternative to a soldered connection using tin solder or solder, for example, an electrically conductive adhesive or one or more wire bonds can be used as a contact connection.

In order to achieve an optimal soldered connection, for example in order to avoid the effect of solder flow, the solution according to the present invention provides for a formation of a first power source side and a first source side.

In an advantageous development of the lead frame proposed according to the present invention, the contact connection is formed by a first formation of a first power source side and a first source side such that the first power source side and the first source side lying next to one another have the first formation having a first deep embossing, wherein the first power source side and the first source side can be contacted at a narrowest point by a first soldered connection by introducing a tin solder.

In order to avoid solder flow, the lead frame can advantageously be formed by an embossing process or, for example, a stamping process. In this case, a distance between the first power source side and the first source side is reduced in places and a deep embossing is carried out at the relevant points, namely at the narrowest point. In this way, a minimal tension is generated locally for the tin solder during the soldering process, which prevents the solder from flowing away. By repeating this formation, a plurality of discrete, predefined positions for the source feedback tap can be created, which are then individually soldered together during production.

In an advantageous development of the lead frame proposed according to the present invention, the first power source side and the first source side can be contacted at the narrowest point by a first adhesive connection or a first welded connection.

In a further advantageous development of the lead frame proposed according to the present invention, the contact connection is formed by a second formation of a first power source side and a first source side such that the first power source side and the first source side lying next to one another have the second formation having a second deep embossing, wherein the first power source side and the first source side can be contacted by a second soldered connection by introducing at least one bridge.

In a further advantageous development of the lead frame proposed according to the present invention, the first power source side and the first source side can be contacted by a second adhesive connection or a second welded connection by introducing at least one metal molded part.

In a further advantageous development of the lead frame proposed according to the present invention, the one or more bridges is/are designed as one or more metal molded parts or as one or more surface resistors.

In a further advantageous development of the lead frame proposed according to the present invention, the contact connection is formed by a third formation of a first power source side and a first source side such that the first power source side and the first source side lying next to one another have the third formation having openings, wherein the first power source side and the first source side can be contacted at the one or more openings by a third soldered connection by introducing at least one jumper.

In a further advantageous development of the lead frame proposed according to the present invention, the first power source side and the first source side can be contacted at a narrowest point by a third adhesive connection or a third welded connection by introducing at least one jumper.

In a further advantageous development of the lead frame proposed according to the present invention, the one or more jumpers is/are designed as one or more through-hole resistors.

In a further advantageous development of the lead frame proposed according to the present invention, the contact connection is formed by a fourth formation of a first power source side and a first source side such that the first power source side and the first source side lying next to one another are formed with one or more solder stops, wherein the first power source side and the first source side can be contacted at the one or more solder stops by a fourth soldered connection by introducing at least the tin solder.

In a further advantageous development of the lead frame proposed according to the present invention, the solder stops formed on the power source side and the source side are designed as a solder resist or a partial oxidation.

A solder resist is a material that is applied to the first power source side and to the first source side, for example in order to protect certain regions from contact with the tin solder during the soldering process or to prevent the tin solder from flowing away. A solder resist can, for example, be made from a polymer photoresist.

In an advantageous development of the lead frame proposed according to the present invention, the power source has one or more elongated holes.

By means of the proposed design of the elongated holes in the power source, the solution according to the present invention flexibly varies a common inductance in the load and control circuit. This is achieved by introducing the elongated holes into the power source, for example by stamping. By utilizing the above-described formations of the first power source side and the first source side, an elongated hole can be at least partially closed by soldering, which can lead to an increase in the effective cross section of the lead frame and thus to a reduction in the inductance. This is possible, for example, in combination with the source feedback tap or with a fixed, unchangeable source feedback tap. The inductance of the MOSFET, for example, can be individually adjusted by changing the cross section.

In an advantageous development of the lead frame proposed according to the present invention, the one or more elongated holes are at least partially closed by a fifth soldered connection by introducing the tin solder.

Furthermore, the present invention relates to the use of the lead frame with the variable source feedback tap in a power module.

The design according to the present invention of the formation of the lead frame advantageously achieves a variable source feedback tap, wherein a formation of the lead frame is advantageously created for different semiconductor or chip configurations. Furthermore, the solution proposed according to the present invention of the source feedback tap creates optimized negative feedback, for example in the event of a short circuit, thereby increasing the resistance to short circuits.

Due to the variable source feedback tap, the inductance of the source feedback tap in the power module can be individually adapted to different power transistors, such as semiconductor component size and/or semiconductor component type, which in particular optimizes the resistance to short circuits.

Furthermore, the formation according to the present invention of the power source of the lead frame advantageously allows a common inductance of the load and control circuit to be flexibly varied by introducing the elongated holes. In this way, the source feedback tap can be more precisely adapted to a power semiconductor component.

Furthermore, the lead frame according to the present invention allows the lead frame to always be designed in the same way regardless of the variant and to be individually and easily adapted, for example, to subsequently developed variants. In addition, adjustments to the characteristics of the source feedback tap can be made during development, such as adjustments to specific customer requirements. The variability according to the present invention of the lead frame thus allows almost cost-neutral customer-specific adaptation at a late stage of production.

### BRIEF DESCRIPTION OF THE DRAWINGS

Example embodiments of the present invention are explained in greater detail with reference to the figures and the following description.

FIG. 1 is a schematic representation of a power module with a lead frame, according to an example embodiment of the present invention.

FIG. 2 is a schematic representation of the power source and source of the lead frame lying next to one another and spaced apart, according to an example embodiment of the present invention.

FIG. 3 is a schematic representation of a behavior of the tin solder, according to an example embodiment of the present invention.

FIG. 4A is a schematic representation of a first formation, according to an example embodiment of the present invention.

FIG. 4B is a detailed schematic representation of a first formation in cross section, according to an example embodiment of the present invention.

FIG. 5A is a schematic representation of a second formation, according to an example embodiment of the present invention.

FIG. 5B is a detailed schematic representation of a second formation in cross section, according to an example embodiment of the present invention.

FIG. 6A is a schematic representation of a third formation, according to an example embodiment of the present invention.

FIG. 6B is a detailed schematic representation of a third formation in cross section, according to an example embodiment of the present invention.

FIG. 7 is a schematic representation of a solder stop, according to an example embodiment of the present invention.

FIG. 8 is a schematic representation of the elongated holes in the power source, according to an example embodiment of the present invention.

### DETAILED DESCRIPTION OF EXAMPLE EMBODIMENTS

In the following description of the embodiments of the present invention, identical or similar elements are denoted by the same reference signs, and a repeated description of these elements in individual cases is dispensed with. The drawings show the subject matter of the present invention only schematically.

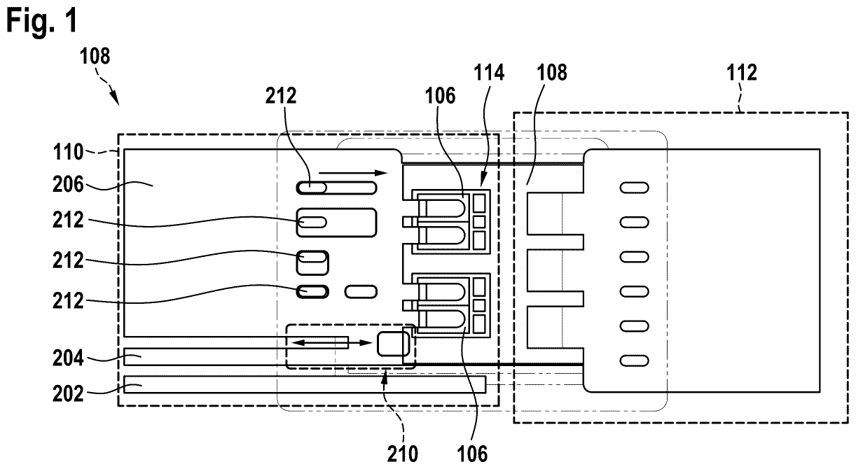

FIG. 1 is a schematic representation of a power module 114 with a lead frame 108. FIG. 1 also shows the power module 114, the lead frame 108 with a first part 110 and a second part 112, and two semiconductor components 106. FIG. 1 also shows that the first part 110 of the lead frame 108 has a gate 202, a source 204 and a power source 206, wherein the gate 202, the source 204 and the power source 206 are arranged next to one another and spaced apart. In the solution according to the present invention, an initial connection point according to the related art is omitted, as a result of which the power source 206 and the source 204 do not touch each other. This design of the lead frame 108 creates the possibility of a variable source feedback tap 210, wherein a contact connection 418 is specifically designed. Furthermore, a plurality of elongated holes 212 in the power source 206 are represented by borders of the elongated holes 212, which are variably formed.

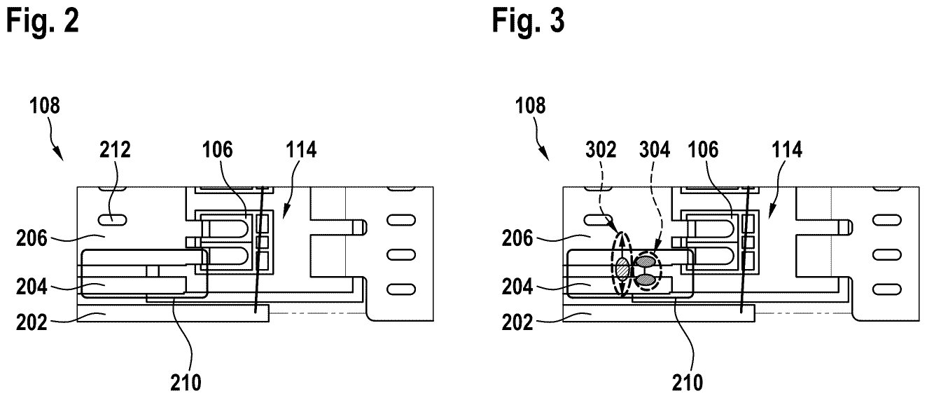

FIG. 2 is a schematic representation of the power source 206 and source 204 of the lead frame 108 arranged next to one another and spaced apart from one another. Furthermore, FIG. 2 at least partially shows the power module 114 and a semiconductor component 106, as well as the lead frame 108 including gate 202, source 204 and power source 206. Furthermore, one region is formed as a variable source feedback tap 210.

FIG. 3 is a schematic representation of the solder behavior. In the region of the source feedback tap 210, two solder joints are shown, wherein the first solder joint represents a solder joint before soldering 302 and the second solder joint represents a solder joint after soldering 304, wherein the effect of solder flow is shown. Furthermore, FIG. 3 at least partially shows the power module 114 and a semiconductor component 106, as well as the lead frame 108 with the gate 202, the source 204 and the power source 206. Furthermore, one region is formed as a variable source feedback tap 210.

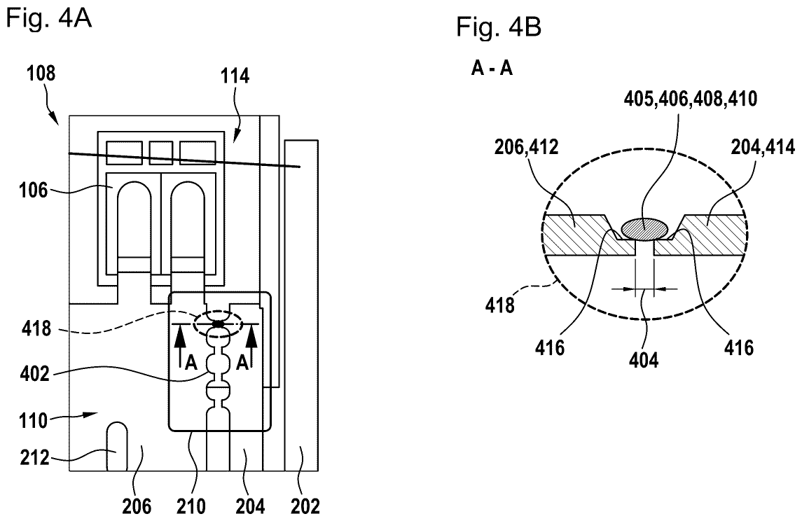

FIG. 4A is a schematic representation of a first formation. FIG. 4A partially shows the power module 114 and a semiconductor component 106, as well as the lead frame 108 with a first part 110 with gate 202, source 204 and power source 206. Furthermore, one region is formed as a variable source feedback tap 210. It can also be seen in FIG. 4A that, in the region of the variable source feedback tap 210, a first formation 402 having a narrowest point 404 is formed at the edges of the power source 206 and the source 204, wherein the contact connection 418 exists at the narrowest point 404.

FIG. 4B is a detailed schematic representation of a first formation 402 of FIG. 4A in cross section. In FIG. 4B, a contact connection 418 is shown as a first soldered connection 405 with tin solder 406 between the power source 206 and the source 204. A first side of the power source 412 and a first side of the source 414 have a first deep embossing 416. Furthermore, the narrowest point 404 between the first power source side 412 and the first source side 414 is shown with the tin solder 406. As an alternative to a first soldered connection 405, a first adhesive connection 408 or a first welded connection 410 is provided as the contact connection 418.

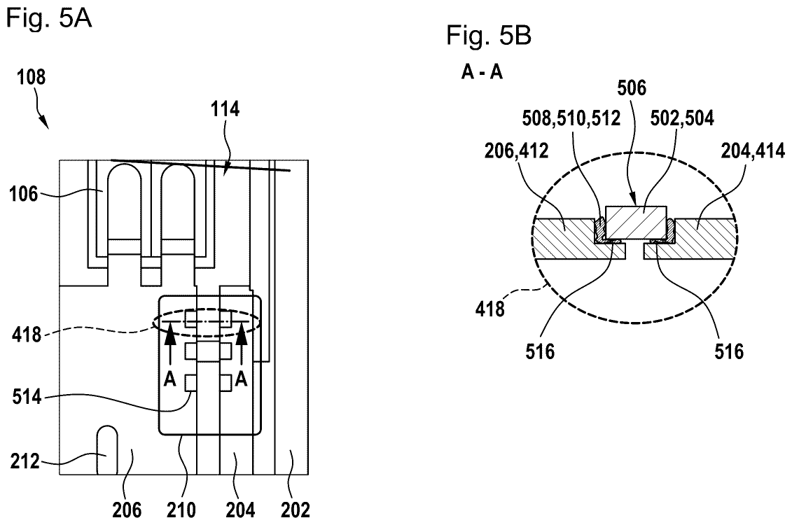

FIG. 5A is a schematic representation of a second embodiment 514 of the power source 206 and the source 204. FIG. 5A partially shows the power module 114 and a semiconductor component 106, as well as the lead frame 108 with the gate 202, the source 204 and the power source 206. Furthermore, one region is formed as a variable source feedback tap 210. It can also be seen in FIG. 5A that, in the region of the variable source feedback tap 210, a second formation 514 having a number of second deep embossings 516 is formed at the edges of the power source 206 and the source 204.

FIG. 5B is a detailed schematic representation of the second formation 514 of FIG. 5A in cross section. FIG. 5B shows a contact connection 418 in the form of a second soldered connection 508 having a bridge 506, for example made of a metal molded part 502 or a surface resistor 504, wherein the bridge 506 is arranged between the first power source side 412 and a first source side 414 of a second deep embossing 516. As an alternative to a second soldered connection 508, a second adhesive connection 510 or a second welded connection 512 is provided as the contact connection 418.

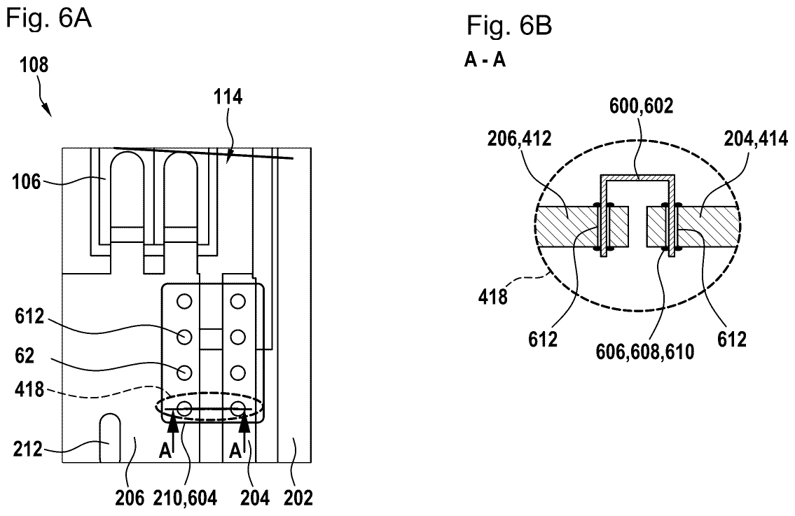

FIG. 6A is a graphical representation of a third embodiment 604 of the power source 206 and the source 204. FIG. 6A partially shows the power module 114 and the semiconductor component 106, as well as the lead frame 108 with the gate 202, the source 204 and the power source 206. Furthermore, one region is formed as a variable source feedback tap 210. It can also be seen in FIG. 6A that, in the region of the variable source feedback tap 210, a third formation 604 having a number of holes 612 is formed at the edges of the power source 206 and the source 204.

FIG. 6B is a detailed schematic representation of the third formation 604 of FIG. 6A in cross section. FIG. 6B shows a contact connection 418. A third soldered connection 606 is arranged in the holes 612 provided for this purpose within the first power source side 412 and the first source side 414, by introducing a jumper 600 or a through-hole resistor 602 between the first power source side 412 and a first source side 414. As an alternative to a third soldered connection 606, a third adhesive connection 608 or a third welded connection 610 can be implemented as a contact connection 418.

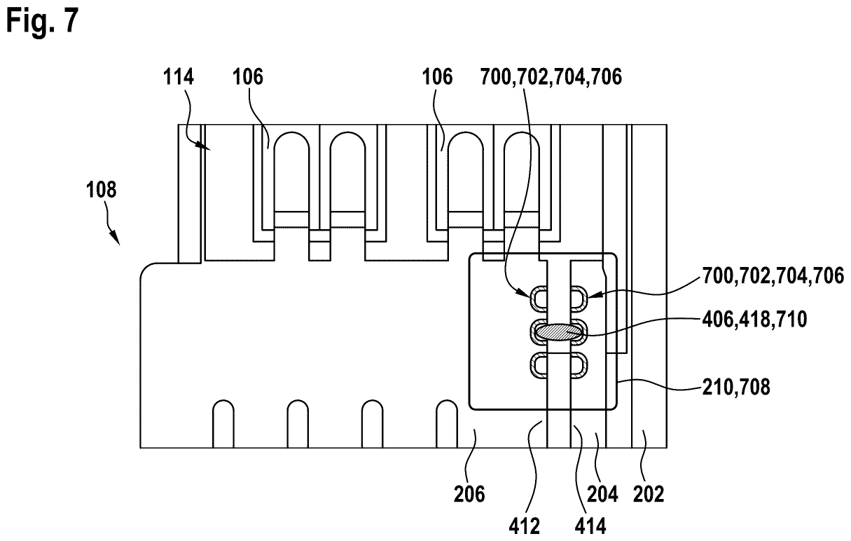

FIG. 7 is a schematic representation of a solder stop 700. FIG. 7 is also a representation of a fourth formation 708 of the power source 206 and the source 204. FIG. 7 partially shows the power module 114 and two semiconductor components 106, as well as the lead frame 108 with the gate 202, the source 204 and the power source 206. Furthermore, one region is formed as a variable source feedback tap 210 with a fourth formation 708. It can also be seen in FIG. 7 that, in the region of the variable source feedback tap 210, a fourth formation 708 with a solder resist 704 or a partial oxidation 706 is formed on the first power source side 412 and the first source side 414 at the edges of the power source 206 and the source 204. The contact connection 418 is further implemented by a fourth soldered connection 710 using tin solder 406. Optionally, the fourth formation 708 can be combined with the first formation 402, the second formation 514 or the third formation 604. As a fourth soldered connection 710, an adhesive connection 408, 510, 608 or a welded connection 410, 512, 610 is alternatively provided as a contact connection 418 according to FIGS. 4B, 5B and 6B.

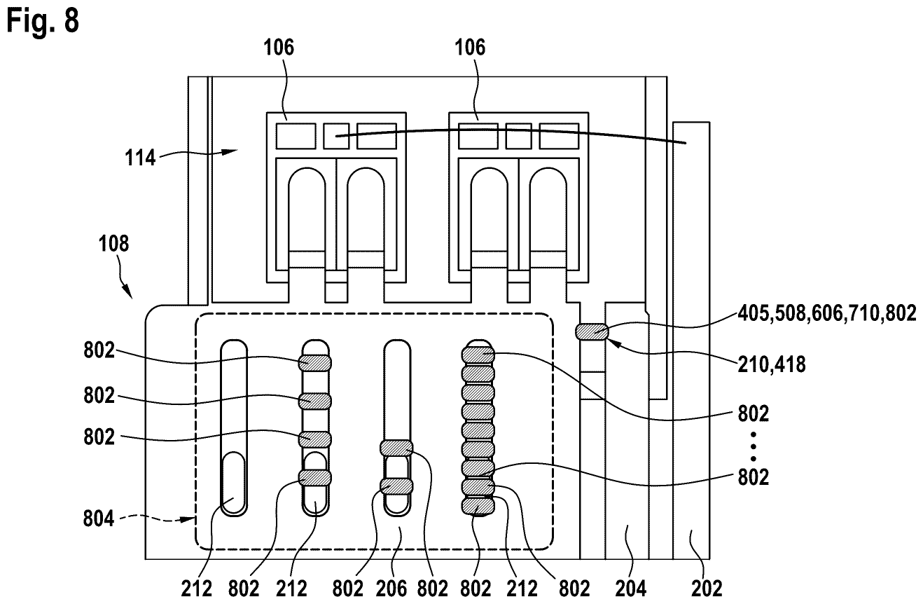

FIG. 8 is a schematic representation of the elongated holes 212 in the power source 206. FIG. 8 is also a schematic representation of the possible first, second, third or fourth formation 402, 514, 604, 708 of the power source 206 and the source 204. FIG. 8 partially shows the power module 114 and two semiconductor components 106, as well as the lead frame 108 with the gate 202, the source 204 and the power source 206. Furthermore, one region is formed as a variable source feedback tap 210 with a fourth formation 708. It can also be seen in FIG. 8 that, in the region 804 of the power source 206, four elongated holes 212 are shown by way of example by marked borders, wherein one of the elongated holes 212 has no connection point, while three further elongated holes 212 have a number of connection points by means of tin solder 412, 802.

The present invention is not limited to the exemplary embodiments described here and the aspects emphasized therein. Rather, a plurality of modifications, which are within the scope of activities of a person skilled in the art in view of the present invention, are possible within the range of the present invention.

1-14. (canceled)

15. A lead frame for a power module for implementing a variable source feedback tap, comprising:
a first part, and a second part, wherein the first part is formed separately from the second part;
wherein the first part has at least one gate, at least one source, and at least one power source, wherein the gate, the source, and the power source are spaced apart from one another in a side-by-side manner;
wherein the variable source feedback tap is made between the power source and the source by a contact connection.

16. The lead frame according to claim 15, wherein the contact connection is formed by a first formation of a first power source side and a first source side such that the first power source side and the first source side lying next to one another have the first formation having a first deep embossing, wherein the first power source side and the first source side can be contacted at a narrowest point by a first soldered connection by introducing a tin solder.

17. The lead frame according to claim 16, wherein the first power source side and the first source side can be contacted at the narrowest point by a first adhesive connection or a first welded connection.

18. The lead frame according to claim 15, wherein the contact connection is formed by a second formation of a first power source side and a first source side such that the first power source side and the first source side lying next to one another have the second formation having a second deep embossing, wherein the first power source side and the first source side can be contacted by a second soldered connection by introducing at least one bridge.

19. The lead frame according to claim 18, wherein the first power source side and the first source side can be contacted by a second adhesive connection or a second welded connection by introducing at least one metal molded part.

20. The lead frame according to claim 18, wherein the at least one bridge is at least one metal molded part or at least one surface resistors.

21. The lead frame according to claim 14, wherein the contact connection is formed by a third formation of a first power source side and a first source side such that the first power source side and the first source side lying next to one another have the third formation having one or more holes, wherein the first power source side and the first source side can be contacted at the one or more holes by a third soldered connection by introducing at least one jumper.

22. The lead frame according to claim 21, wherein the first power source side and the first source side can be contacted at a narrowest point by a third adhesive connection or a third welded connection by introducing at least one jumper.

23. The lead frame according to claim 21, wherein the at least one jumper is formed as at least one through-hole resistor.

24. The lead frame according to claim 15, wherein the contact connection is formed by a fourth formation of a first power source side and of a first source side such that the first power source side and the first source side lying next to one another are formed with one or more solder stops, wherein the first power source side and the first source side can be contacted at the one or more solder stops by a fourth soldered connection by introducing at least the tin solder.

25. The lead frame according to claim 24, wherein the one or more solder stops formed on the power source side and the source side are formed as a solder resist or a partial oxidation.

26. The lead frame according to claim 15, wherein the power source has one or more elongated holes.

27. The lead frame according to claim 26, wherein the one or more elongated holes are at least partially closed by a fifth soldered connection by introducing a tin solder.

28. The lead frame according to claim 15, wherein the lead frame is used with a variable source feedback tap within the power module.
